(19) United States
(12) Patent Application Publication
(10) Pub. No.: US 2025/0271553 A1
(43) Pub. Date: Aug. 28, 2025

(54) LIDAR CHIP AND LIDAR SYSTEM

(71) Applicant: BEIJING MORELITE SEMICONDUCTOR CO., LTD., Beijing (CN)

(72) Inventors: Guomin JIANG, Beijing (CN); Tianbo SUN, Beijing (CN); Yunsong WANG, Beijing (CN); Jun WANG, Beijing (CN); Zhi LI, Beijing (CN); Jie SUN, Beijing (CN)

(21) Appl. No.: 19/192,006

(22) Filed: Apr. 28, 2025

Related U.S. Application Data
(63) Continuation of application No. PCT/CN2023/129243, filed on Nov. 2, 2023.

(30) Foreign Application Priority Data
Nov. 2, 2022 (CN) 202211364231.1

(51) Int. Cl. G01S 7/481

(52) U.S. Cl. CPC G01S 7/4814; G01S 7/4817

(57) ABSTRACT

Provided are a LiDAR chip and a LiDAR system. The chip includes: a substrate; N laser transmission channels to transmit N detection light beams, a light-transmitting end of i-th laser transmission channel is to emit i-th detection light beam, the detection light beams are respectively reflected after encountering an obstacle to generate N reflected light beams, i-th detection light beam corresponds to i-th reflected light beam, N and i are positive integers, N≥1, 1≤i≤N; and N laser detection channels corresponding to the N laser transmission channels in a one-to-one correspondence, to transmit the N reflected light beams, a light-receiving end of i-th laser detection channel is to receive the i-th reflected light beam, the laser transmission channels and the laser detection channels are arranged alternately, at least part of the laser transmission channels adopts a SiN waveguide, and the laser detection channels adopt silicon waveguides.

### CROSS-REFERENCE TO RELATED APPLICATION

This application is a continuation of a PCT application No. PCT/CN2023/129243, which claims a priority to Chinese Patent Application No. 202211364231.1 filed on Nov. 2, 2022, the disclosures of which are incorporated in their entirety by reference herein.

### TECHNICAL FIELD

The present disclosure relates to the technical field of a laser radar, and in particular, to a Light Detection And Ranging (LiDAR) chip and a LiDAR system.

### BACKGROUND

A LiDAR system is a radar system that detects characteristic variables such as a position and a velocity of a target by emitting a laser beam. The working principle of the LiDAR system is to transmit a detection signal to the target, then compare a received signal reflected back from the target with the transmitted detection signal, and after appropriate processing, obtain related information of the target, such as parameters such as a distance, an orientation, a height, a speed, a posture, or even a shape of the target, so as to detect, track and identify targets such as an aircraft or a missile. LiDAR systems are now widely deployed in different scenarios, including automated vehicles. The LiDAR system may actively estimate the distance and the speed of an environmental feature when scanning the environmental feature, and generate a point location cloud indicating a three-dimensional shape of the environmental feature. The LiDAR system is one of core sensors widely used in autonomous driving scenarios, and may be used to collect three-dimensional information of an external environment. According to a detection mechanism, the LiDAR system may be mainly divided into two LiDAR systems of Time of Flight (Time of Flight) and Frequency Modulated Continuous Wave (FMCW).

### SUMMARY

A Light Detection and Ranging (LiDAR) chip is provided in some embodiments of the present disclosure. The LiDAR chip includes: a substrate; N laser transmission channels on the substrate and configured to transmit N detection light beams, wherein each of the N laser transmission channels has one light-transmitting end, a light-transmitting end of an i-th laser transmission channel is configured to emit an i-th detection light beam, the N detection light beams are respectively reflected after encountering an obstacle to generate N reflected light beams, the i-th detection light beam corresponds to an i-th reflected light beam, N and i are positive integers, N≥2, and 1≤i≤N; and N laser detection channels on the substrate and corresponding to the N laser transmission channels in a one-to-one correspondence, and configured to transmit the N reflected light beams, wherein each of the N laser detection channels has one light-receiving end, and a light-receiving end of the i-th laser detection channel is configured to receive the i-th reflected light beam, wherein the N laser transmission channels and the N laser detection channels are arranged alternately, and at least part of the N laser transmission channels adopts a SiN waveguide, and the N laser detection channels adopt silicon waveguides.

In some embodiments, a distance between the light-transmitting end of the i-th laser transmission channel and the light-receiving end of the i-th laser detection channel is equal to a distance between a light-transmitting end of an (i+1)-th laser transmission channel and a light-receiving end of the (i+1)-th laser detection channel.

In some embodiments, a distance between light-transmitting ends of any two adjacent laser transmission channels is equal to a distance between light-receiving ends of any two adjacent laser transmission channels.

In some embodiments, the LiDAR chip further includes: a receiving port, configured to receive a laser beam; an optical splitter, configured to split the laser beam to a detection laser and a local-oscillation laser; a first beam splitter, disposed between the optical splitter and the N laser transmission channels and configured to split the detection laser into the N detection light beams; and a second beam splitter, disposed between the optical splitter and the N laser detection channels, configured to split the local-oscillation laser into N local oscillation light beams, wherein the N local oscillation light beams respectively enter the N laser detection channels.

In some embodiments, the i-th laser detection channel has: a mixer configured to receive the i-th local oscillation light beam and the i-th reflected light beam, and perform a frequency-mixing operation on the i-th local oscillation light beam and the i-th reflected light beam to obtain a frequency-mixed beam; and a detector configured to receive the frequency-mixed beam and detect a beat frequency between the i-th local oscillation light beam and the i-th reflected light beam to obtain a measurement result.

A Light Detection And Ranging (LiDAR) system is provided in the present disclosure. The LiDAR system includes: the LiDAR chip according to the above embodiments; a lens assembly configured to collimate and deflect a detection light beam emitted by the light-transmitting end of the i-th laser transmission channel, and perform focusing on the i-th reflected light beam to be coupled to the light-receiving end of the i-th laser detection channel; and a beam scanning guide device, disposed on a side of the lens assembly close to the obstacle, and configured to adjust an emission direction of the i-th detection light beam emitted by the light-transmitting end of the i-th transmission channel over time to realize beam scanning.

In some embodiments, the lens assembly includes a first lens assembly, the i-th detection light beam includes TE-mode polarized light, the i-th reflected light beam includes TM-mode polarized light, the LiDAR system further includes a polarization beam bias device disposed between the first lens assembly and the LiDAR chip, wherein the polarization beam bias device is configured to allow the TM-mode polarized light beam to pass in an original direction, and translates and bias the TE-mode polarized light beam passing through the polarization beam bias device; a light-transmitting end of the i-th laser transmission channel emits an i-th detection light beam in a direction parallel to an optical axis of the first lens assembly, the i-th detection light beam sequentially passes through the first lens assembly and the beam-scanning guide assembly and reaches the obstacle to form an i-th reflected light beam after being translated and biased by the polarization beam bias device, the i-th reflected light beam is returned to the polarization beam bias device along an original optical path, and passes through the polarization beam bias device with the original direction being unchanged, and the i-th reflected light beam is incident to a light receiving end of the i-th laser detection channel in a direction parallel to the optical axis of the first lens assembly.

In some embodiments, a distance between the light-transmitting end of the i-th laser transmission channel and the light-receiving end of the i-th laser detection channel is substantially equal to a bias distance d of the polarization beam bias device to the TE-mode polarized light beam, and the bias distance d satisfies the following formula:

$$tan ( α ) = ( 1 - \frac{{n}_{o}^{2}}{{n}_{e}^{2}} ) \cdot \frac{tan ( θ )}{1 + \frac{{n}_{o}^{2}}{{n}_{e}^{2}} \cdot {tan}^{2} ( θ )} \\ d = L \times tan ( α )$$

wherein L is the thickness of the polarization beam bias device, α is a deflection angle of the polarization beam bias device to the TM-mode polarized light, θ is the angle between an optical axis of the polarization beam bias device and a wave vector, nₒ is a refractive index of the TM-mode polarized light in the polarization beam bias device, and nₑ is a refractive index of the TE-mode polarized light beam in the polarization beam bias device.

In some embodiments, the i-th laser detection channel has a polarization rotator, configured to transform the received TM-mode polarized light to the TE-mode polarized light.

In some embodiments, the LiDAR system further includes: a laser source, docked with the LiDAR chip and configured to generate the laser beam.

Compared with the related art, the above solution of the embodiments of the present disclosure at least has the following beneficial effects: the LiDAR chip has the laser transmission channels and the laser detection channels arranged alternately, the laser transmission channels can adopt a SiN waveguide, thereby reducing the detection laser loss and improving the output power of the LiDAR system. In the LiDAR system having the above LiDAR chip, the polarization beam bias device may be designed to be smaller, and miniaturization of the LiDAR system is achieved.

### BRIEF DESCRIPTION OF THE DRAWINGS

The accompanying drawings, which are incorporated in and constitute a part of this specification, illustrate embodiments consistent with the present disclosure and, together with the description, serve to explain the principles of the present disclosure. Obviously, the accompanying drawings in the following description are merely some embodiments of the present disclosure, and for a person of ordinary skill in the art, other drawings may be obtained according to these drawings without creative efforts. In the drawings:

FIG. 1 is a schematic structural diagram of a multi-channel LiDAR system according to some embodiments of the present disclosure;

FIG. 2 is a schematic structural diagram of a receiving chip according to some embodiments of the present disclosure;

FIG. 3 is a schematic structural diagram of a LiDAR system according to some embodiments of the present disclosure;

FIG. 4 is a schematic structural diagram of a LiDAR system according to some embodiments of the present disclosure;

FIG. 5 is a schematic structural diagram of a LiDAR system according to some embodiments of the present disclosure;

FIG. 6 is a partial schematic structural diagram of the LiDAR chip in FIG. 5; and

FIG. 7 is a waveform diagram of a detection light beam and a receiving light beam in an FWCW frequency-swept manner provided by the present disclosure.

### DETAILED DESCRIPTION

In order to make the objectives, technical solutions, and advantages of the present disclosure clearer, the present disclosure will be further described in detail below with reference to the accompanying drawings. All other embodiments obtained by a person of ordinary skill in the art based on the embodiments of the present disclosure without creative efforts shall fall within the protection scope of the present disclosure.

The terms used in the embodiments of the present disclosure are merely for the purpose of describing particular embodiments, and are not intended to limit the present disclosure. As used in the embodiments of the present disclosure and the appended claims, the singular forms “a”, “an” and “the” are also intended to include plural forms, unless the context clearly indicates other meanings, “a plurality of” generally includes at least two.

It should be understood that the term “and/or” used in this specification is merely an association relationship for describing associated objects, indicating that there may be three relationships, for example, A and/or B may indicate that A exists alone, A and B exist at the same time, and B exists alone. In addition, the character “/” in this specification generally indicates an “or” relationship between the associated objects.

It should be understood that although the terms first, second, third, etc. may be used in the embodiments of the present disclosure to describe, the present application should not be limited to these terms. These terms are only used to distinguish different objects. For example, first may also be referred to as second, and similarly, second may also be referred to as first without departing from the scope of the embodiments of the present disclosure.

It should also be noted that the terms “comprising,” “including,” or any other variation thereof are intended to cover a non-exclusive inclusion, so that a commodity or apparatus including a series of elements not only includes those elements, but also includes other elements that are not explicitly listed, or further includes elements inherent to the commodity or apparatus. In the absence of more restrictions, an element defined by the sentence “including a” does not exclude that there are additional identical elements in the commodity or apparatus that includes the element.

The LiDAR system mainly includes the following two technical routes: Time of Flight (TOF) and Frequency-Modulated Continuous Wave (FMCW), according to a ranging principle. The ranging principle of TOF is that the distance is measured by multiplying the time of flight of the light pulse between the target object and the LiDAR system by the speed of light, and the TOF LiDAR system adopts a pulse amplitude modulation technology. Different from the TOF route, the FMCW route mainly enables the return light to interfere with the local light by sending and receiving a continuous laser beam, measures the frequency difference between the transmitted light and the return light by using a frequency mixing detection technology, and then calculates the distance of the target object through the frequency difference. In short, TOF uses time to measure the distance, while FMCW uses frequency to measure the distance. Compared with TOF, FMCW has the following advantages: the optical wave of the TOF route is easily interfered by ambient light, and the anti-interference capability of the FMCW is strong; the signal-to-noise ratio of the TOF is too low, the signal-to-noise ratio of FMCW is very high, the data quality of the speed dimension of the TOF is low, and the FMCW can obtain the data of the speed dimension of each pixel.

In the present disclosure, an FMCW LiDAR system is used as an example for description.

In the related art, the LiDAR chip is of a single-chip structure, the light-transmitting end and the light-receiving end of the chip are of an integrated structure, there is an overlapping portion between the laser transmission channel and the laser detection channel, and since active devices such as a mixer and a detector needs to be arranged in the laser detection channel, the laser transmission channel and the laser detection channel usually only use a silicon waveguide to transmit laser. Moreover, the damage threshold of the silicon waveguide is relatively low, and the laser has relatively a high loss when passing through the silicon waveguide, resulting that the maximum output power of the LiDAR system is limited, which is not easy to further be improved.

The present disclosure provides a LiDAR chip which includes: a substrate; N laser transmission channels on the substrate and configured to transmit N detection light beams, each laser transmission channel has one light-transmitting end, the light-transmitting end of the i-th laser transmission channel is configured to emit an i-th detection light beam, the N detection light beams are reflected respectively to generate N reflected light beams after encountering an obstacle, the i-th detection light beam corresponds to the i-th reflected light beam, N and i are positive integers, and N≥2, 1≤i≤N; and N laser detection channels on the substrate, which are in one-to-one correspondence with the N laser transmission channels and are configured to transmit the N reflected light beams, each laser detection channel has one light-receiving end, and the light-receiving end of the i-th laser detection channel is configured to receive an i-th reflected light beam; the N laser transmission channels and the N laser detection channels are arranged alternately, and at least one part of the N laser transmission channels is made of a SiN waveguide, and the laser detection channels are made of a silicon waveguide.

The LiDAR chip in the present disclosure includes the N laser transmission channels and the N laser detection channels that are arranged alternately, and the laser transmission channels may adopt SiN waveguides, thereby reducing the loss of the detection laser and improving the output power of the LiDAR system.

Optional embodiments of the present disclosure are described in detail below with reference to the accompanying drawings.

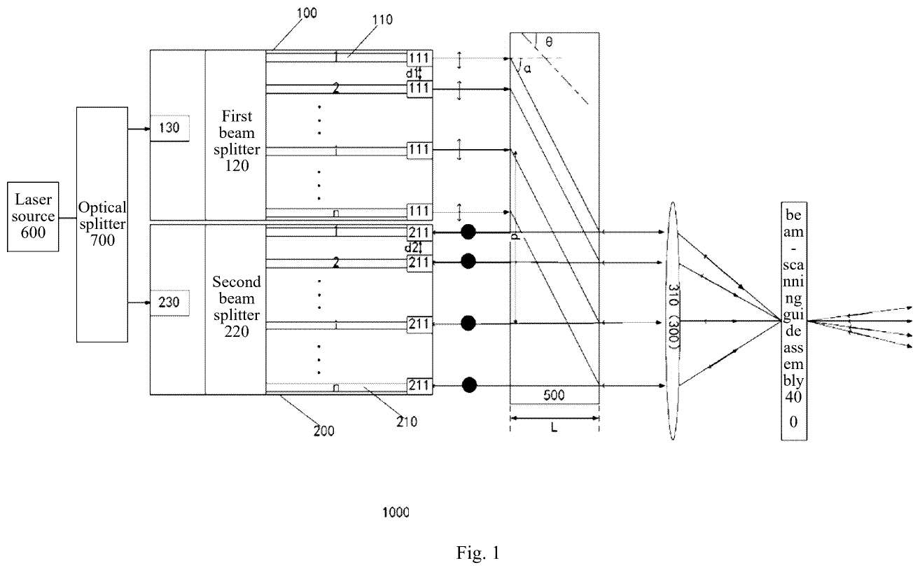

FIG. 1 is a schematic structural diagram of a multi-channel LiDAR system according to some embodiments of the present disclosure. As shown in FIG. 1, the present disclosure provides a LiDAR system 1000, the LiDAR system 1000 includes a transmitting chip 100 and a receiving chip 200, the transmitting chip 100 is configured to emit a detection light beam, the receiving chip 200 is configured to receive a reflected light beam and mix the reflected light beam with a local oscillation light beam to detect a target, for example, a distance and a speed of the obstacle, herein, a distance between an obstacle and the LiDAR system and a speed of the obstacle, wherein the distance between the obstacle and the LiDAR system and the speed of the obstacle refers to a speed of the obstacle relative to the LiDAR system.

The transmitting chip 100 has N laser transmission channels 110 configured to transmit N detection light beams, each laser transmission channel 110 has one light-transmitting end 111, the light-transmitting end 111 of the i-th laser transmission channel 110 is configured to emit an i-th detection light beam, the N detection light beams are respectively reflected to generate N reflected light beams after encountering an obstacle, the i-th detection light beam corresponds to an i-th reflected light beam, N and I are positive integers, and N≥1, 1≤i≤N.

The receiving chip 200 has N laser detection channels 210, which are in one-to-one correspondence with the N laser transmission channels 110 and are configured to transmit the N reflected light beams, each laser detection channel 210 has one light-receiving end 211, and the light-receiving end 211 of the i-th laser detection channel 210 is configured to receive the i-th reflected light beam.

It should be understood by those skilled in the art that, for the i-th detection light beam, diffuse reflection usually occurs on the obstacle when the i-th detection light beam is irradiated on the obstacle, and thus the reflected light beam corresponding to the i-th detection light beam should be reflected towards various directions, but for the LiDAR system, only the reflected light beam returned along at least a part of the original path of the light exiting path of the detection light beam is received by the corresponding light-receiving end of the i-th laser detection channel, that is, only the reflected light beam returned along at least a part of the original path of the light exiting path of the detection light beam can be effectively utilized, and the i-th reflected light beam herein is the reflected light beam returned along at least a part of the light exiting path of the corresponding i-th detection light beam.

At least a part of the N laser transmission channels 110 is at least one of a SiN waveguide, a SiO2 waveguide, and an optical fiber array, and the laser detection channel 210 adopts a silicon waveguide. The SiN waveguide, the SiO2 waveguide, and the optical fiber array have better laser transmission characteristics than the silicon waveguide, and have a relatively high damage threshold and are not easy to be damaged. The transmission loss of the laser in the SiN waveguide, the SiO2 waveguide, and the optical fiber array is relatively low, especially in the SiO2 waveguide, the transmission loss rate is lower than 0.5 dB/km.

In some embodiments, the transmitting chip 100 is, for example, a passive chip, there is no need to provide an active device on the transmitting chip 100, and a SiN-based and/or glass-based chip may be used, to ensure that the laser is transmitted with a lower loss inside the transmitting chip.

In some embodiments, as shown in FIG. 1, the transmitting chip 100 may include a detection laser receiving port 130 and a first beam splitter 120. The detection laser receiving port 130 is configured to detect that the laser receiving port 130 is configured to receive a detection laser, for example, the detection laser is input into the transmitting chip 110 from the outside. The first beam splitter 120 is disposed between the detection laser receiving port 130 and the N laser transmission channels 110, and is configured to split the detection laser into the N detection light beams.

In some embodiments, as shown in FIG. 1, the receiving chip 200 is, for example, an active chip, for example, a silicon-based chip, on which an active device needs to be disposed. In some embodiments, the receiving chip 200 includes a local-oscillation laser receiving port 230 and a second beam splitter 220, the local-oscillation laser receiving port 230 is configured to receive a local oscillation laser, and the local oscillation laser is input into the receiving chip 200 for example from the outside. The second beam splitter 220 is disposed between the local-oscillation laser receiving port 230 and the N laser detection channels 210, and is configured to split the local oscillation laser into N local oscillation light beams LO, where the N local oscillation light beams LO respectively enter the N laser detection channels.

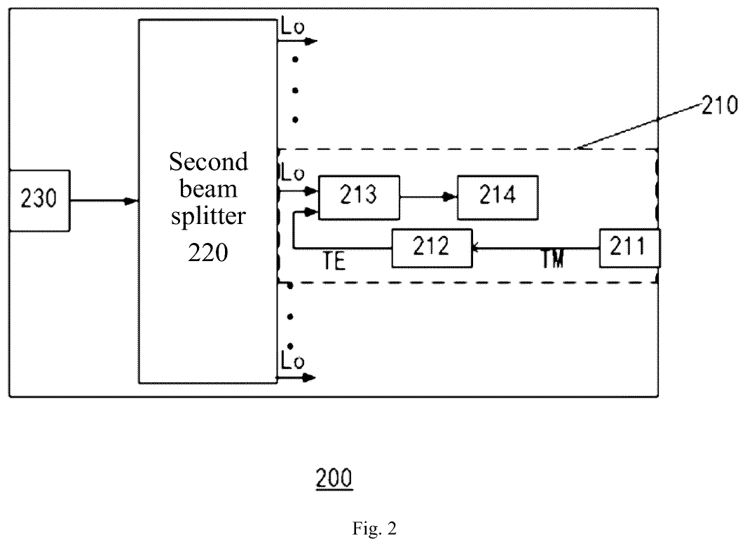

FIG. 2 is a schematic structural diagram of a receiving chip according to some embodiments of the present disclosure, and shows a schematic structure of a laser detection channel. In some embodiments, as shown in FIG. 2, each laser detection channel 210 has a mixer 213 and a detector 214, taking the i-th laser detection channel 210 as an example, where the mixer 213 is configured to receive the i-th local oscillation light beam LO and the i-th reflected light beam, and perform a frequency-mixing operation on the i-th local oscillation light beam and the i-th reflected light beam to obtain a mixed beam. The detector 214 is configured to receive the mixed beam and detect a beat frequency between the i-th local oscillation light beam and the i-th reflected light beam to obtain a measurement result. That is, the distance and/or speed of the obstacle is obtained. The beat frequency refers to a frequency difference between the local oscillation light beam and the reflected light beam.

In some embodiments, as shown in FIG. 2, each laser detection channel 210 further includes a polarization rotator 212. In the present application, the detection light beam includes a TE-mode polarized light beam, and the TE-mode polarized light beam generates the reflected light beam including a TM-mode polarized light beam after being reflected by the obstacle. For the i-th laser detection channel 210, the TM-mode polarized light beam enters the laser detection channel 210 through the light-receiving end 211, and the polarization rotator 212 changes the polarization mode of the TM-mode polarized light beam to generate a TE-mode polarized light beam, which is beneficial to mixing, with the TE-mode polarized light beam, the local oscillation light beam which is also the TE-mode polarized light beam.

Those skilled in the art may understand that the waveguides on the chip of the LiDAR system (including the transmitting chip and/or the receiving chip) usually only transmit the TE-mode polarized light beam, that is, the detection light beam emitted by the chip of the LiDAR system is usually a TE-mode polarized light beam. However, the TE-mode polarized light beam usually generates natural light after being reflected by an obstacle, but only a part, i.e., the TM-mode polarized light, of the natural light is received and is used for detection, and for another part of the natural light which is, for example, the TE-mode polarized light is usually not utilized. In the case that there is no special description in the present disclosure, the i-th reflected light beam generally refers to the reflected TM-mode polarized light beam.

In some embodiments, as shown in FIG. 1, the LiDAR system 1000 further includes a laser light source 600 and an optical splitter 700.

The laser light source 600 is configured to generate a laser, at least a portion of which is used as a detection light beam to perform detection, such as detecting a distance and/or a speed of the obstacle. The laser light source 600 is, for example, a semiconductor laser light source. The laser light source 600 may be directly modulated by a chirp signal. That is, the chirp signal for driving and controlling the laser light source 600 may be input to the laser light source 600 with a time varying intensity, so that the laser light source 600 generates and outputs a frequency-swept beam, that is, a beam whose frequency varies within a predetermined range. In some embodiments, the laser light source 600 may further include a modulator that receives a modulation signal, and the modulator may be configured to modulate the laser beam based on the modulation signal, so that the laser light source 600 generates and outputs a frequency-swept beam, that is, a light beam whose frequency changes in a predetermined range. The frequency of the laser beam output by the laser light source 600 when the laser light source 600 is not modulated is substantially constant, referred to as the frequency of the unmodulated light beam, for example, 100 to 300 THz. The frequency-swept light beam may be output by the laser light resource 600 after modulation. The frequency range of the frequency-swept light beam is related to the frequency of the unmodulated light beam. The laser light source 600 is, for example, an external light source, which is introduced into the transmitting chip 100 through an optical path (for example, an optical fiber).

The optical splitter 700 is configured to split the laser into the detection laser and the local oscillation laser. The detection laser and the local oscillation laser have the same frequency at any time point, that is, the frequency modulation waveforms of the detection laser and the local oscillation laser are completely the same. For example, the optical splitter 700 may introduce the detection laser into the transmitting chip 100 through an optical path (for example, an optical fiber), and for example, is docked with a detection laser receiving port 130 of the transmitting chip 100 through an optical fiber. For example, the optical splitter 700 may introduce the local oscillation laser into the receiving chip 200 through an optical path (for example, an optical fiber), for example, be docked with the laser receiving port 230 of the receiving chip 200 by using an optical fiber.

In some embodiments, at least one of the laser light source 600 and the optical splitter 700 may also be integrated on a semiconductor chip, for example, integrated on the receiving chip 200.

In some embodiments, as shown in FIG. 1, the LiDAR system 1000 further includes a lens assembly 300 and a beam-scanning guide assembly 400

The lens assembly 300 may be a lens or a lens group, and has focusing and collimating functions, and is configured to perform collimation and deflection on the detection light beam emitted by the light-transmitting end of the i-th transmission channel, and perform focusing on the i-th reflected light beam to be coupled to the light-receiving end of the i-th laser detection channel.

The beam-scanning guide assembly 400 is disposed on a side of the lens assembly 300 close to the obstacle, and is configured to adjust an emission direction of the i-th detection light beam emitted from the light-transmitting end of the i-th transmission channel over time to implement beam scanning. The beam-scanning guide assembly 400 is, for example, an optical phased array (OPA), and can guide the direction of the light beam by dynamically controlling the optical characteristics of the surface on the microscopic scale. In other embodiments, the beam-scanning guide assembly may further include a grating, a mirror galvanometer, a polygon mirror, a MEMS mirror, or a combination of an optical phased array (OPA) with the grating, the mirror galvanometer, the polygon mirror, or the MEMS mirror.

In some embodiments, as shown in FIG. 1, the lens assembly 300 includes a first lens assembly 310, and the first lens assembly 310 is, for example, a convex lens. The transmitting chip 100 and the receiving chip 200 are arranged side by side, the N detecting light beams are TE-mode polarized light beams, the polarization direction of the N detecting light beams is shown in FIG. 1, parallel to the paper and is shown by using vertical lines with arrows at both ends, and the N reflected light beams are all TM-mode polarized light beams, the polarization direction of the N reflected light beams is shown in FIG. 1, and is perpendicular to the paper and marked with black dots. The first lens assembly 310 is disposed between the combination of the transmitting chip 100 and the receiving chip 200 and the beam-scanning guide assembly 400.

As shown in FIG. 1, the LiDAR system 1000 further includes a polarization beam bias device 500 which is, for example, disposed between the first lens assembly 310 and the combination of the transmitting chip 100 and the receiving chip 200, and the polarizing beam shifter 500 is configured to allow the TM-mode polarized light beam to pass with the original polarization direction unchanged, and horizontally shift the TE-mode polarized light beam passing through the polarized light shifter 500.

The following specifically explains the transmission path of the detection light beam and the reflected light beam, and takes the i-th laser transmission channel and the i-th detection light beam emitted thereby and the i-th laser detection channel and the i-th reflected light beam corresponding to the i-th laser transmission channel and the i-th reflected light beam as an example.

As shown in FIG. 1, the light-transmitting end 111 of the i-th laser transmission channel 110 emits an i-th detection light beam in a direction parallel to the optical axis of the first lens assembly 310, and the i-th detection light beam sequentially passes through the polarization beam bias device 500, the first lens assembly 310, and the beam-scanning guide assembly 400 to reach the obstacle and form the i-th reflected light beam.

Specifically, the i-th detection light beam is a TE-mode polarized light beam entering the polarization beam bias device 500 in a direction parallel to the optical axis of the first lens assembly 310, the polarization beam bias device 500 enables the i-th detection light beam to be horizontally bias towards the optical axis of the first lens assembly 310, and the i-th detection light beam is still transmitted toward the first lens assembly 310 along a direction parallel to the optical axis of the first lens assembly 310 after being transmitted from the polarization beam bias device 500, specifically, the i-th detection light beam is translated by a predetermined distance d after passing through the polarization beam bias device 500, the predetermined distance d is referred to as a bias distance d, and the transmission direction of the i-th detection light beam is unchanged. The first lens assembly 310 collimates the i-th detection light beam and deflects it towards the optical axis of the first lens assembly 310. The i-th detection light beam has a certain divergence angle, and after passing through the first lens assembly 310, the i-th detection light beam is collimated into a parallel beam, and is deflected towards the optical axis of the first lens assembly 310. The beam-scanning guide assembly 400 adjusts the exit direction of the i-th detection light beam over time to achieve beam scanning.

After the i-th detection light beam encounters an obstacle, an i-th reflected light beam is formed and includes a TM-mode polarized light beam, the i-th reflected light beam is returned to the polarization beam bias device 500 along an original optical path, the polarization beam bias device 500 does not change the traveling direction of the i-th reflected light beam, the i-th reflected light beam is incident to the light-receiving end 211 of the i-th laser detection channel in the direction parallel to the optical axis of the first lens assembly. Specifically, the i-th reflected light beam is a TM-mode polarized light beam, and the i-th reflected light beam is returned to the polarization beam bias device 500 along the optical path of the i-th detection light beam, and keeps the traveling direction and is incident to the light-receiving end 211 of the i-th laser detection channel

In some embodiments, as shown in FIG. 1, the distance between the light-transmitting end 111 of the i-th laser transmission channel 110 and the light-receiving end 211 of the i-th laser detection channel 210 is substantially equal to the bias distance d of the polarization beam bias device to the TE-mode polarized light beam, so that the i-th reflected light beam can be coupled into the light-receiving end 211 of the i-th laser detection channel 210, so as to facilitate subsequent frequency-mixing and detection.

### The Bias Distance d Satisfies the Following Formula:

$$tan ( α ) = ( 1 - \frac{{n}_{o}^{2}}{{n}_{e}^{2}} ) \cdot \frac{tan ( θ )}{1 + \frac{{n}_{o}^{2}}{{n}_{e}^{2}} \cdot {tan}^{2} ( θ )} \\ d = L \times tan ( α )$$

where L is the thickness of the polarization beam bias device, α is the deflection angle of the polarization beam bias device to the TM-mode polarized light beam, θ is the angle between the optical axis of the polarization beam bias device and the wave vector, nₒ is the refractive index of the TM-mode polarized light beam in the polarization beam bias device, nₑ is the refractive index of the TE-mode polarized light beam in the polarization beam bias device, as shown in FIG. 1, the wave vector is, for example, the horizontal direction, and the optical axis of the polarization beam bias device is marked by the discontinuous line.

In some embodiments, as shown in FIG. 1, the light-transmitting ends 111 of the N laser transmission channels 110 on the transmitting chip 100 are arranged at equal intervals at a first distance d1, the light-receiving ends 211 of the N laser detection channels 210 of the receiving chip 200 are spaced at equal intervals by a second distance d2, and the first distance d1 is equal to the second distance d2. In this way, when the transmitting chip 100 and the receiving chip 200 are arranged side by side, the distance between the light-transmitting end 111 of each laser transmission channel 110 and the light-receiving end 211 of the laser detection channel 210 corresponding to the laser transmission channel 110 is equal, and multi-channel detection of the LiDAR system is realized by cooperating with the appropriate polarization beam bias device 500.

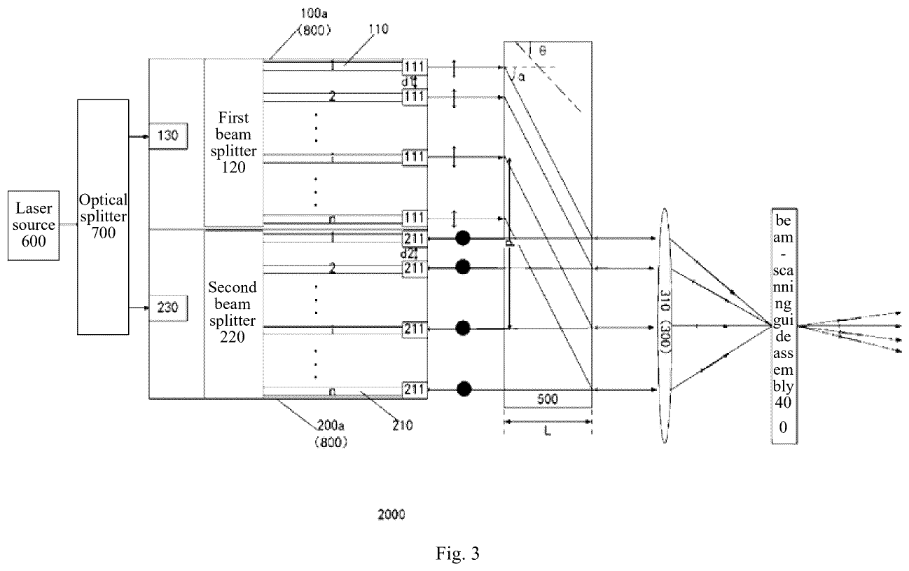

In some embodiments, the transmitting chip 100 and the receiving chip 200 adopt an integrated structure, and are formed on the same substrate by a patterning process. FIG. 3 is a schematic structural diagram of a LiDAR system according to some embodiments of the present disclosure. The embodiment shown in FIG. 3 is substantially the same as the structure of the embodiment shown in FIG. 1, with the same components being numbered the same. The same structure of the two is not described herein, and the differences between the two are mainly described in detail below.

As shown in FIG. 3, some embodiments of the present disclosure provide a LiDAR system 2000, which includes, for example, a laser light source 600, an optical splitter 700, a LiDAR chip 800, a polarization beam bias device 500, a first lens assembly 310, and a beam-scanning guide assembly 400.

The LiDAR chip 800 corresponds to the combination of the transmitting chip 100 and the receiving chip 200 in the LiDAR system 1000 in the embodiment shown in FIG. 1. That is, the transmitting chip and the receiving chip are integrally formed by using a semiconductor process. Specifically, the LiDAR chip 800 is, for example, a silicon-based chip, which includes a transmitting region 100a and a receiving region 200a.

The transmitting region 100a corresponds to the transmitting chip 100 in FIG. 1, has N laser transmission channels 110, and is configured to transmit N detection light beams, each laser transmission channel 110 has one light-transmitting end 111, the light-transmitting end 111 of the i-th laser transmission channel 110 is configured to emit an i-th detection light beam, the N detection light beams are respectively reflected to generate N reflected light beams after encountering an obstacle, the i-th detection light beam corresponds to an i-th reflected light beam, N and i are positive integers, and N≥1, 1≤i≤N.

The receiving region 200a corresponds to the receiving chip 200 in FIG. 1, has N laser detection channels 210 in one-to-one correspondence with the N laser transmission channels 110 and is configured to transmit the N reflected light beams, each laser detection channel 210 has one light-receiving end 211, and the light-receiving end 211 of the i-th laser detection channel 210 is configured to receive the i-th reflected light beam.

At least a part of the N laser transmission channels 110 adopts a SiN waveguide, and the laser detection channel 210 adopts a silicon waveguide. The SiN waveguide has better laser transmission characteristics than the silicon waveguide, and has a relatively high damage threshold and is not easy to be damaged.

In some embodiments, the LiDAR chip 800 as a whole is made of a silicon-based substrate, the LiDAR chip 800 is divided into a transmitting region 100a and a receiving region 200a; in the transmitting region 100a, a SiN layer is formed on the silicon-based substrate, and then other passive devices such as SiN waveguides are formed thereon. In the receiving region 200a, a silicon waveguide and some active devices, such as mixers, detectors, etc. are formed on the silicon-based substrate.

Compared with the defect that two independent chips are spliced side by side and tedious alignment and large alignment deviation are generated, a single chip is adopted to divide two regions, various components are synchronously formed on the single chip by adopting a semiconductor process, the position relationship among the components is more accurate, the deviation is small, and a complex alignment process is not needed. For example, the distance between the light-transmitting end 111 of each laser transmission channel 110 and the light-receiving end 211 of the corresponding laser detection channel 210 may be kept consistent by using an accurate semiconductor process. The distance between the light-transmitting ends 111 of any two adjacent laser transmission channels 110 is also consistent, and the distance between the light-receiving ends 211 of any two adjacent laser detection channels 210 is also consistent. The reflected light beam corresponding to the detection light beam emitted by each laser transmission channel 110 can be accurately received by the corresponding laser detection channel 210, and the detection accuracy of the LiDAR system is implemented.

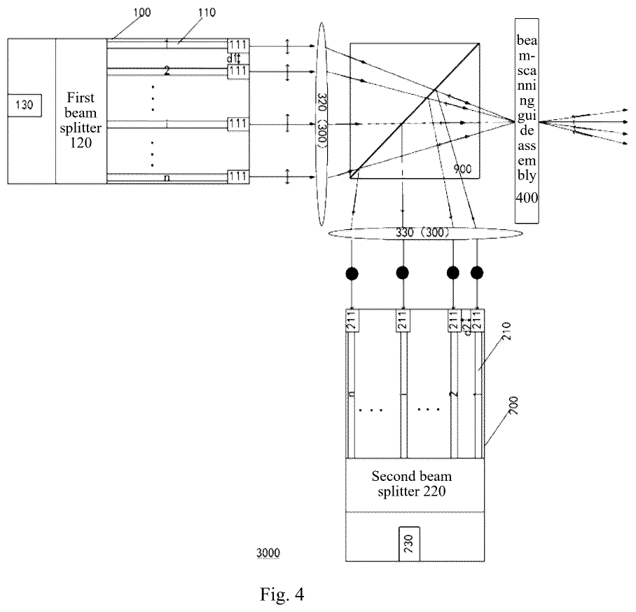

FIG. 4 is a schematic structural diagram of a LiDAR system according to some embodiments of the present disclosure. The embodiment shown in FIG. 4 is substantially the same as the structure of the embodiment shown in FIG. 1, with the same components being numbered the same. The same structure of the two is not described herein, and the differences between the two are mainly described in detail below.

As shown in FIG. 4, some embodiments of the present disclosure provide a LiDAR system 3000, which includes, for example, a transmitting chip 100, a receiving chip 200, a lens assembly 300, and a beam-scanning guide assembly 400, the LiDAR system 3000 may also include a laser light source and an optical splitter.

As shown in FIG. 4, the lens assembly 300 includes a second lens assembly 320 and a third lens assembly 330, both of which are, for example, convex lenses. The N detection light beams are TE-mode polarized light beams, and the N reflected light beams are TM-mode polarized light beams.

The LiDAR system 3000 further includes a polarization beam splitter 900 configured to allow TE-mode polarized light beams to pass through with the polarization direction being unchanged, and to deflect TM-mode polarized light beams passing through the polarization beam splitter, e.g. the reflected TM-mode polarized light beams. In this embodiment, the polarization beam splitter 900 is used to replace the polarization beam bias device 500 in FIG. 1 to guide the TM-mode polarized light beams.

As shown in FIG. 4, the transmitting chip 100 and the receiving chip 200 are separately disposed, the second lens assembly 320 is disposed between the transmitting chip 100 and the polarizing beam splitter 900, and is configured to collimate the N detecting light beams emitted by the transmitting chip 100, and the third lens 330 is disposed between the receiving chip 200 and the polarizing beam splitter 900 and is used to focus the N light beams, so that the N light beams are coupled into the N laser detecting channels of the receiving chip 200.

The following specifically explains the transmission path of the detection light beam and the reflected light beam, and takes the i-th laser transmission channel and the i-th detection light beam emitted by the i-th laser transmission channel and the i-th laser detection channel and the i-th reflected beam corresponding to the i-th laser transmission channel and the i-th detection light beam as an example.

As shown in FIG. 4, the light-transmitting end 11 of the i-th laser transmission channel 110 emits an i-th detection light beam in a direction parallel to the optical axis of the second lens assembly 320, the i-th detection light beam sequentially passes through the second lens assembly 320, the polarization beam splitter 900, the beam-scanning guide assembly 400 to reach the obstacle and form an i-th reflected light beam, and the i-th reflected light beam passes through the polarization beam splitter 900 along the original optical path and passes through the third lens assembly 330 after being deflected by the polarization beam splitter, and is incident to the light-receiving end 211 of the i-th laser detection channel 210 in the direction parallel to the optical axis of the third lens assembly 330

Specifically, the i-th detection light beam is a TE-mode polarized light beam, and is transmitted towards the second lens assembly 320 in a direction parallel to the optical axis of the second lens assembly 320, and the second lens assembly 320 performs collimation on the i-th detection light beam and deflects the i-th detection light beam towards the optical axis of the second lens assembly 320. The i-th detection light beam has a certain divergence angle, and after passing through the second lens assembly 320, the i-th detection light beam is collimated into a parallel beam, and is deflected towards the optical axis of the second lens assembly 320. The i-th detection light beam as the TE-mode polarized light beam does not change the transmission direction after passing through the polarization beam splitter 900, and is incident to the beam-scanning guide assembly 400, and the beam-scanning guide assembly 400 adjusts the exiting direction of the i-th detection light beam over time to adjust the exiting direction of the i-th detection light beam over time to realize beam-scanning.

After the i-th detection light beam encounters an obstacle, an i-th reflected light beam is formed, which includes TM-mode polarized light, the i-th reflected light beam is returned to the polarizing beam splitter 900 along an original optical path, the i-th reflected light beam passing through the polarizing beam splitter 900 deflects and is incident onto the third lens assembly 330. An included angle exists between the optical axis of the third lens assembly 330 and the optical axis of the second lens assembly 320, for example, 90°, as shown in FIG. 4. For example, the i-th reflected light beams are parallel beams, and the third lens assembly 330 focuses the i-th reflected light beam to the light-receiving end 211 of the i-th laser detection channel 210, so that the i-th reflected light beam is conveniently coupled into the i-th laser detection channel 210.

With this structure, the transmitting chip 100 and the receiving chip 200 need not be precisely aligned, and the two need to be aligned with the second lens assembly 320 and the third lens assembly 330, respectively, so that the system is simple and convenient to assemble.

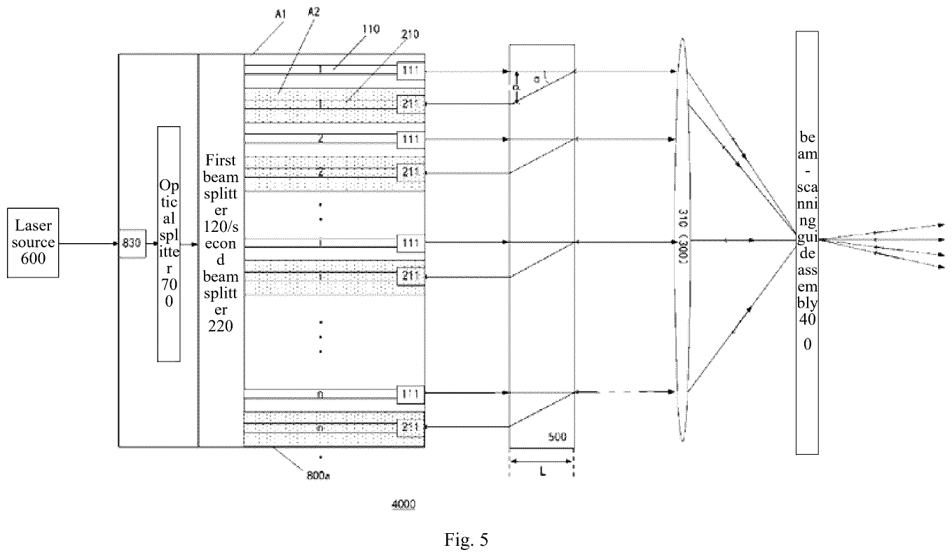

FIG. 5 is a schematic structural diagram of a LiDAR system according to some embodiments of the present disclosure. The embodiment shown in FIG. 5 is substantially the same as the structure of the embodiment shown in FIG. 3, with the same components being numbered the same. The same structure of the two is not described herein, and the differences between the two are mainly described in detail below.

As shown in FIG. 5, some embodiments of the present disclosure provide a LiDAR chip 800a and a LiDAR system 4000 including the LiDAR chip 800a.

The LiDAR chip 800a includes a substrate, and N laser transmission channels 110 and N laser detection channels 210 disposed on the substrate, for example, a silicon-based substrate.

The N laser transmission channels 110 are disposed on the substrate and configured to transmit N detection light beams, each laser transmission channel 110 has one light-transmitting end 111, the light-transmitting end 111 of the i-th laser transmission channel 110 is configured to emit an i-th detection light beam, the N detection light beams are respectively reflected to generate N reflected light beams after encountering an obstacle, the i-th detection light beam corresponds to the i-th reflected light beam, N and i are positive integers, and N≥1, 1≤i≤N.

The N laser detection channels 210 are disposed on the substrate, correspond to the N laser transmission channels 110 on a one-to-one basis, and are configured to transmit the N reflected light beams, each laser detection channel 210 has one light-receiving end 211, and the light-receiving end 211 of the i-th laser detection channel 210 is configured to receive the i-th reflected light beam.

The N laser transmission channels 110 and the N laser detection channels 210 are alternately arranged, at least a part of the N laser transmission channels is a SiN waveguide, and the laser detection channel adopts a silicon waveguide. The SiN waveguide has better laser transmission characteristics than the silicon waveguide, and has a relatively high damage threshold and is not easy to be damaged. The transmission loss of the laser in the SiN waveguide is relatively low.

Specifically, as shown in FIG. 5, the substrate of the LiDAR chip 800a may be divided into N transmitting sub-regions A1 and N receiving sub-regions A2, each transmitting sub-region A1 is provided with a laser transmission channel 110, and each receiving sub-region A2 is provided with one laser detection channel 210. The N transmitting sub-regions A1 and the N receiving sub-regions A2 are alternately arranged. In the transmitting sub-regions A1, a SiN layer is formed on the silicon-based substrate, and then passive devices such as SiN waveguides are formed. In the receiving sub-regions A2, a silicon waveguide and an active device are directly formed on the silicon-based substrate.

In some embodiments, as shown in FIG. 5, the distance between the light-transmitting end of the i-th laser transmission channel and the light-receiving end of the i-th laser detection channel is equal to the distance between the light-transmitting end of the (i+1)th laser transmission channel and the light-receiving end of the (i+1)th laser detection channel. That is, the distance between the light-transmitting end 111 of each laser transmission channel 110 and the light-receiving end 211 of the corresponding laser detection channel 210 is the same predetermined value.

In some embodiments, the distance between the light-transmitting ends 111 of any two adjacent laser transmission channels 110 is equal to the distance between the light-receiving ends 211 of any two adjacent laser detection channels 210.

In some embodiments, as shown in FIG. 5, the LiDAR chip 800a further includes a receiving port 830, an optical splitter 700, a first beam splitter 120, and a second beam splitter 220.

The receiving port 830 is configured to receive a laser. The detection laser is input into the LiDAR chip 800a for the outside. The optical splitter 700 is configured to split the laser into a detection laser and a local oscillation laser, and the detection laser and the local oscillation laser have the same frequency at any time point, that is, the frequency modulation waveforms of the detection laser and the local oscillation laser are completely the same.

The first beam splitter 120 is disposed between the optical splitter 700 and the N laser transmission channels 110, and is configured to split the detection laser into the N detection light beams. The second beam splitter 220 is disposed between the optical splitter 700 and the N laser detection channels 210, and is configured to split the local oscillation laser into N local oscillation light beams, where the N local oscillation light beams respectively enter the N laser detection channels 210, and the first beam splitter 120 and the second beam splitter 220 are, for example, an integrated structure.

In some embodiments, the receiving port 830, the optical splitter 700, the first beam splitter 120, and the second beam splitter 220 may all be passive devices, and the area where the receiving port 830, the optical splitter 700, the first beam splitter 120, and the second beam splitter 220 may form a SiN layer on a silicon-based substrate to form a SiN waveguide, which is conducive to reducing the loss of the laser during transmission between the devices.

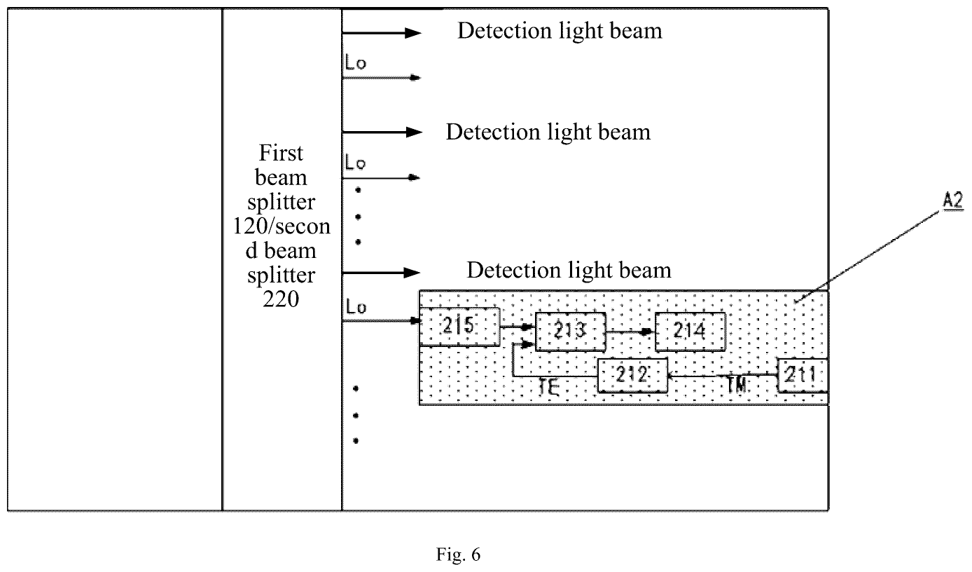

FIG. 6 is a partial schematic structural diagram of the LiDAR chip in FIG. 5, which shows a schematic structure of a laser detection channel in a receiving sub-region. In some embodiments, as shown in FIG. 6, each laser detection channel 210 has a mixer 213 and a detector 214, taking the i-th laser detection channel 210 as an example, where the mixer 213 is configured to receive the i-th local oscillation light beam LO and the i-th reflected light beam, and perform a frequency-mixing operation on the i-th local oscillation light beam and the i-th reflected light beam to obtain a mixed beam. The detector 214 is configured to receive the mixed beam and detect a beat frequency between the i-th local oscillation light beam and the i-th reflected light beam to obtain a measurement result. That is, the distance and/or speed of the obstacle is obtained. The beat frequency refers to a frequency difference between the local oscillation light beam and the reflected light beam.

In some embodiments, as shown in FIG. 6, each laser detection channel 210 further includes a polarization rotator 212. In the present application, the detection beam is for example a TE-mode polarized light beam, which is reflected by the obstacle to generate a reflected light beam, the reflected light beam is a TM-mode polarized light beam. For the i-th laser detection channel 210, the TM-mode polarized light beam enters the laser detection channel 210 through the light-receiving end 211, and the polarization rotator 212 changes the polarization mode of the TM-mode polarized light beam to form the TE-mode polarized light beam, which is beneficial to mixing the local oscillation light beam with the same TE-mode polarized light beam.

In some embodiments, as shown in FIG. 6, each laser detection channel 210 further includes a waveguide converter 215, configured to convert a SiN waveguide into a silicon-based waveguide to ensure transmission of the local oscillation light beam LO.

In some embodiments, as shown in FIG. 5, the LiDAR system 4000 further includes a lens assembly 300 and the beam-scanning guide assembly 400, the lens assembly 300 may be a lens or a lens group, and has focusing and collimation functions, and is configured to perform collimation and deflection on the detection light beam emitted by the light-transmitting end of the i-th transmission channel, and perform focusing on the i-th reflected light beam to be coupled to the light-receiving end of the i-th laser detection channel.

The beam-scanning guide assembly 400 is disposed on a side of the lens assembly 300 close to the obstacle, and is configured to adjust an emission direction of the i-th detection light beam emitted from the light-transmitting end of the i-th transmission channel over time to implement beam scanning. The beam-scanning guide assembly 400 is, for example, an optical phased array (OPA), and can guide the direction of the light beam by dynamically controlling the optical characteristics of the surface on the microscopic scale. In other embodiments, the beam-scanning guide assembly may further include a grating, a mirror galvanometer, a polygon mirror, a MEMS mirror, or a combination of an optical phased array (OPA) and the foregoing apparatus.

In some embodiments, as shown in FIG. 5, the lens assembly 300 includes a first lens assembly 310, and the first lens assembly 310 is, for example, a convex lens. The N detection light beams are TE-mode polarized light, the polarization direction of the N detection light beams is shown in FIG. 5 to be parallel to the paper and marked by vertical lines with arrows at both ends, the N reflected light beams are all TM-mode polarized light, the polarization direction of the N reflected light beams is shown in FIG. 1 to be perpendicular to the paper, and marked with black dots. The first lens assembly 310 is disposed between the LiDAR chip 800a and the beam-scanning guide assembly 400.

As shown in FIG. 5, the LiDAR system 1000 further includes a polarization beam bias device 500, for example, disposed between the first lens assembly 310 and the LiDAR chip 800a, and the polarization beam bias device 500 is configured to allow the TM-mode polarized light beam to pass through in an original direction, and translate and bias the TE-mode polarized light beam passing through the polarization beam bias device 500.

The following specifically explains the transmission paths of the detection light beam and the reflected light beam, and take the i-th laser transmission channel and the i-th detection light beam emitted by the i-th laser transmission channel and the i-th laser detection channel and the i-th reflected light beam corresponding to the i-th laser transmission channel as an example.

As shown in FIG. 5, the light-transmitting end 111 of the i-th laser transmission channel 110 emits the i-th detection light beam in a direction parallel to the optical axis of the first lens assembly 310, and the i-th detection light beam sequentially passes through the polarization beam bias device 500, the first lens assembly 310, and the beam-scanning guide assembly 400 to reach the obstacle and form the i-th reflected light beam.

Specifically, the i-th detection light beam includes TE-mode polarized light, and enters the polarization beam bias device 500 in a direction parallel to the optical axis of the first lens assembly 310, and the polarization beam bias device 500 enables the i-th detection light beam to be horizontally biased toward the optical axis of the first lens assembly 310, and is still transmitted toward the first lens assembly 310 along a direction parallel to the optical axis of the first lens assembly 310, specifically, the i-th detection light beam is translated by a predetermined distance d after passing through the polarization beam bias device 500, the predetermined distance d is referred to as a bias distance d, and the transmission direction is unchanged. The first lens assembly 310 collimates the i-th detection light beam and deflects it towards the optical axis of the first lens assembly 310. The i-th detection light beam has a certain divergence angle, and after passing through the first lens assembly 310, the i-th detection light beam is collimated into a parallel beam, and is deflected towards the optical axis of the first lens assembly 310. The beam-scanning guide assembly 400 adjusts the exiting direction of the i-th detection light beam over time to achieve beam scanning.

After the i-th detection light beam encounters an obstacle, an i-th reflected light beam is formed and includes TM-mode polarized light, the i-th reflected light beam is returned to the polarization beam bias device 500 along an original optical path, the polarization beam bias device 500 does not change the traveling direction of the i-th reflected light beam, the i-th reflected light beam is incident to the light-receiving end 211 of the i-th laser detection channel in the direction parallel to the optical axis of the first lens assembly, the i-th reflected light beam is TM-mode polarized light, and the i-th reflected light beam is returned to the polarization beam bias device 500 along the optical path of the i-th detection light beam, and is incident to the light-receiving end 211 of the i-th laser detection channel with the travelling direction unchanged.

In some embodiments, as shown in FIG. 5, the distance between the light-transmitting end 111 of the i-th laser transmission channel 110 and the light-receiving end 211 of the i-th laser detection channel 210 is substantially equal to the bias distance d of the polarization beam bias device to the TE-mode polarized light, so that the i-th reflected light beam can be coupled into the light-receiving end 211 of the i-th laser detection channel 210, so as to facilitate subsequent frequency-mixing and detection.

### The Bias Distance d Satisfies the Following Formula:

$$tan ( α ) = ( 1 - \frac{{n}_{o}^{2}}{{n}_{e}^{2}} ) \cdot \frac{tan ( θ )}{1 + \frac{{n}_{o}^{2}}{{n}_{e}^{2}} \cdot {tan}^{2} ( θ )} \\ d = L \times tan ( α )$$

where L is the thickness of the polarization beam bias device, α is the deflection angle of the polarization beam bias device to the TM-mode polarized light, θ is the angle between the optical axis of the polarization beam bias device and the wave vector, nₒ is the refractive index of the TM-mode polarized light beam in the polarization beam bias device, and nₑ is the refractive index of the TE-mode polarized light beam in the polarization beam bias device.

Compared with the embodiment shown in FIG. 1, the polarization beam bias device in the embodiment shown in FIG. 5 may be designed to be smaller, so that the overall miniaturization of the LiDAR system is achieved.

In some embodiments, as shown in FIG. 5, the LiDAR system 4000 further includes a laser light source 600 connected to the LiDAR chip 800 an and configured to generate a laser.

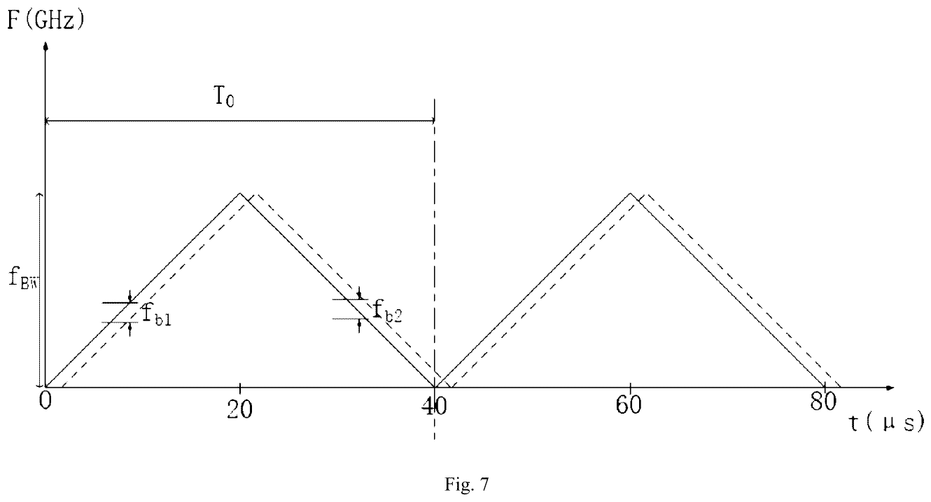

FIG. 7 is a waveform diagram of a detection light beam and a receiving light beam in an FWCW frequency-swept manner according to the present disclosure. As shown in FIG. 7, the frequency-swept optical signal of the detection light beam emitted by the multi-channel LiDAR system is represented by a solid line, the solid line reflects the curve of the frequency of the emergent beam over time, the frequency-swept optical signal is, for example, a periodic triangular wave signal, the reflected optical signal of the reflected light beam received by the LiDAR system is represented by a dashed line, the dashed line reflects the curve of the frequency of the received reflected light beam changing with time, the reflected optical signal is also, for example, a periodic triangular wave signal, and there is a delay between the reflected optical signal and the frequency-swept optical signal.

Only two frequency-swept measurement periods are shown in FIG. 7. In each frequency-swept measurement period, the frequency-swept optical signal includes one frequency-increasing phase and one frequency-decreasing phase, and correspondingly, the corresponding reflected optical signal also includes one frequency-increasing phase and one frequency-decreasing phase.

As shown in FIG. 7, the horizontal coordinate represents time, the unit is s, the vertical coordinate represents frequency, the unit is GHz, the frequency of the detection light beam is increased from 0 to 4 GHz, and then decreases from 4 GHz to 0, and changes in this way periodically. Correspondingly, the frequency of the received reflected light beam is increased from 0 to 4 GHz, for example, as the time increases, and then the frequency is reduced from 4 GHz to 0, and changes periodically.

For any measurement point, the distance R of the obstacle is determined by the following formula:

$$R = \frac{{C}_{0}}{8} \frac{{T}_{0}}{{f}_{BW}} ( {f}_{b 1} + {f}_{b 2} )$$

where T₀ is a preset frequency-sweeping measurement period, f_{BW} is the preset frequency-sweeping bandwidth, f_{b1} is a beat frequency in a frequency-increasing stage, f_{B2} is a beat frequency in a frequency-decreasing stage, and Co is a speed of light.

### The Speed V of the Obstacle Satisfies the Following Relationship:

$$v = - \frac{{C}_{0}}{4} \frac{1}{{f}_{0}} ( {f}_{b 1} - {f}_{b 2} )$$

where Co is the speed of light, f_{b1} is the beat frequency of the frequency-increasing stage, f_{b2} is the beat frequency in the frequency-decreasing stage, and f₀ is the frequency of the unmodulated light beam.

In this specification, each part is described in parallel and progressive manners, each part focuses on a difference from other parts, and the same or similar parts among the parts may be obtained by referring to each other.

With regard to the above description of the disclosed embodiments, the features described in the embodiments of the present disclosure may be replaced or combined with each other, so that those skilled in the art can implement or use the present disclosure. Various modifications to these embodiments will be apparent to those skilled in the art, and the general principles defined herein may be implemented in other embodiments without departing from the spirit or scope of the present disclosure. Thus, the present disclosure will not be limited to the embodiments shown herein but is to be accorded the widest scope consistent with the principles and novel features disclosed herein.

Finally, it should be noted that the embodiments in this specification are described by way of example, each embodiment focuses on differences from other embodiments, and the same or similar parts between the embodiments may be obtained by referring to each other. For the system or device disclosed in the embodiment, since it corresponds to the method disclosed in the embodiments, the description is relatively simple, and for the relevant parts, reference may be made to the description of the method.

Although the present disclosure has been described in detail with reference to the foregoing embodiments, a person of ordinary skill in the art should understand that the technical solutions described in the foregoing embodiments may still be modified, or some of the technical features may still be equivalently replaced; and these modifications or replacements do not make the essence of the corresponding technical solutions depart from the spirit and scope of the technical solutions of the embodiments of the present disclosure.

What is claimed is:

1. A Light Detection and Ranging (LiDAR) chip, comprising:
a substrate;
N laser transmission channels on the substrate and configured to transmit N detection light beams, wherein each of the N laser transmission channels has one light-transmitting end, a light-transmitting end of an i-th laser transmission channel is configured to emit an i-th detection light beam, the N detection light beams are respectively reflected after encountering an obstacle to generate N reflected light beams, the i-th detection light beam corresponds to an i-th reflected light beam, N and i are positive integers, N≥2, and 1≤i≤N; and
N laser detection channels on the substrate and corresponding to the N laser transmission channels in a one-to-one correspondence, and configured to transmit the N reflected light beams, wherein each of the N laser detection channels has one light-receiving end, and a light-receiving end of the i-th laser detection channel is configured to receive the i-th reflected light beam,
wherein the N laser transmission channels and the N laser detection channels are arranged alternately, and at least part of the N laser transmission channels adopts a SiN waveguide, and the N laser detection channels adopt silicon waveguides.

2. The LiDAR chip according to claim 1, wherein a distance between the light-transmitting end of the i-th laser transmission channel and the light-receiving end of the i-th laser detection channel is equal to a distance between a light-transmitting end of an (i+1)-th laser transmission channel and a light-receiving end of the (i+1)-th laser detection channel.

3. The LiDAR chip according to claim 1, wherein a distance between light-transmitting ends of any two adjacent laser transmission channels is equal to a distance between light-receiving ends of any two adjacent laser transmission channels.

4. The LiDAR chip according to claim 1, wherein the LiDAR chip further comprises:
a receiving port, configured to receive a laser beam;
an optical splitter, configured to split the laser beam to a detection laser and a local-oscillation laser;
a first beam splitter, disposed between the optical splitter and the N laser transmission channels and configured to split the detection laser into the N detection light beams; and
a second beam splitter, disposed between the optical splitter and the N laser detection channels, configured to split the local-oscillation laser into N local oscillation light beams, wherein the N local oscillation light beams respectively enter the N laser detection channels.

5. The LiDAR chip according to claim 1, wherein the i-th laser detection channel has:
a mixer configured to receive the i-th local oscillation light beam and the i-th reflected light beam, and perform a frequency-mixing operation on the i-th local oscillation light beam and the i-th reflected light beam to obtain a frequency-mixed beam; and
a detector configured to receive the frequency-mixed beam and detect a beat frequency between the i-th local oscillation light beam and the i-th reflected light beam to obtain a measurement result.

6. A Light Detection And Ranging (LiDAR) system, comprising:
the LiDAR chip according to claim 1;
a lens assembly configured to collimate and deflect a detection light beam emitted by the light-transmitting end of the i-th laser transmission channel, and perform focusing on the i-th reflected light beam to be coupled to the light-receiving end of the i-th laser detection channel; and
a beam scanning guide device, disposed on a side of the lens assembly close to the obstacle, and configured to adjust an emission direction of the i-th detection light beam emitted by the light-transmitting end of the i-th transmission channel over time to realize beam scanning.

7. The LiDAR system according to claim 6, wherein the lens assembly comprises a first lens assembly, the i-th detection light beam comprises TE-mode polarized light, the i-th reflected light beam comprises TM-mode polarized light,
the LiDAR system further comprises a polarization beam bias device disposed between the first lens assembly and the LiDAR chip, wherein the polarization beam bias device is configured to allow the TM-mode polarized light beam to pass in an original direction, and translates and bias the TE-mode polarized light beam passing through the polarization beam bias device;
a light-transmitting end of the i-th laser transmission channel emits an i-th detection light beam in a direction parallel to an optical axis of the first lens assembly, the i-th detection light beam sequentially passes through the first lens assembly and the beam-scanning guide assembly and reaches the obstacle to form an i-th reflected light beam after being translated and biased by the polarization beam bias device, the i-th reflected light beam is returned to the polarization beam bias device along an original optical path, and passes through the polarization beam bias device with the original direction being unchanged, and the i-th reflected light beam is incident to a light-receiving end of the i-th laser detection channel in a direction parallel to the optical axis of the first lens assembly.

8. The LiDAR system according to claim 7, wherein a distance between the light-transmitting end of the i-th laser transmission channel and the light-receiving end of the i-th laser detection channel is substantially equal to a bias distance d of the polarization beam bias device to the TE-mode polarized light beam, and the bias distance d satisfies the following formula:
$$tan ( α ) = ( 1 - \frac{{n}_{o}^{2}}{{n}_{e}^{2}} ) \cdot \frac{tan ( θ )}{1 + \frac{{n}_{o}^{2}}{{n}_{e}^{2}} \cdot {tan}^{2} ( θ )} \\ d = L \times tan ( α )$$
wherein L is the thickness of the polarization beam bias device, α is a deflection angle of the polarization beam bias device to the TM-mode polarized light, θ is the angle between an optical axis of the polarization beam bias device and a wave vector, nₒ is a refractive index of the TM-mode polarized light in the polarization beam bias device, and nₑ is a refractive index of the TE-mode polarized light beam in the polarization beam bias device.

9. The LiDAR system according to claim 6, wherein the i-th laser detection channel has a polarization rotator, configured to transform the received TM-mode polarized light to the TE-mode polarized light.

10. The LiDAR system according to claim 6, wherein the LiDAR system further comprises:
a laser source, docked with the LiDAR chip and configured to generate the laser.
